(19) United States
(12) Patent Application Publication
(10) Pub. No.: US 2012/0304460 A1
(43) Pub. Date: Dec. 6, 2012

(54) MODULE MANUFACTURING METHOD

(75) Inventors: Jun'ichi Kimura, Osaka (JP); Tomohide Ogura, Mie (JP); Takayuki Hiruma, Osaka (JP); Masahisa Nakaguchi, Mie (JP); Misao Kanba, Mie (JP); Motoyoshi Kitagawa, Mie (JP)

(73) Assignee: PANASONIC CORPORATION, Osaka (JP)

(21) Appl. No.: 13/589,782

(22) Filed: Aug. 20, 2012

Related U.S. Application Data
(63) Continuation of application No. PCT/JP2011/000718, filed on Feb. 9, 2011.

(30) Foreign Application Priority Data
Feb. 19, 2010 (JP) 2010-034460

(51) Int. Cl. H05K 3/10; H05K 1/02

(52) U.S. Cl. 29/850; 174/251

(57) ABSTRACT

In a method for manufacturing a module, a substrate is placed above a resin bath while a electronic component is directed downward. In addition, a resin thrown into the resin bath is softened until it becomes flowable. Then, a first surface of the substrate is brought into contact with a liquid surface of the softened resin. The softened resin is allowed to flow forcibly into a gap between the substrate and the electronic component. Then, the resin cures, and a resin portion is formed. Further, a metal thin film is formed on the surface of the resin portion by sputtering to form the shield metal film.

This application is a Continuation of International Application No. PCT/JP11/000718, filed on Feb. 9, 2011, claiming priority of Japanese Patent Application No. 2010-034460, filed on Feb. 19, 2010, the entire contents of each of which are hereby incorporated by reference.

### TECHNICAL FIELD

The present disclosure relates to a method for manufacturing a module in which an electronic component mounted on a resin substrate is covered by a resin, and a circuit formed of the electronic component is shielded.

### BACKGROUND ART

First, conventional module 1 will be described. FIG. 10 is a cross sectional view of conventional module 1. Printed circuit board 2 is made of a thermosetting resin. Electronic component 3 is mounted on an upper surface of printed circuit board 2. Here, electronic component 3 is a semiconductor device, and the semiconductor device and printed circuit board 2 are connected to each other by wire bonding. Although it is not illustrated, electronic components other than the semiconductor device are also mounted on printed circuit board 2. These electronic components form a high-frequency circuit. Resin portion 4 is formed on an upper surface of printed circuit board 2, and electronic component 3 is buried in resin portion 4. Connection pattern 5 connected to the ground of the high-frequency circuit is formed in a peripheral end portion of the upper surface of printed circuit board 2.

Shield film 6 is a thick film conductor and is formed to cover an upper surface and side surfaces of resin portion 4 and a part of a side surface of printed circuit board 2. An end portion of connection pattern 5 is arranged to be exposed from a side surface of resin portion 4, and the connection pattern 5 is electrically connected to shield film 6 at this exposing portion.

Next, a method for manufacturing module 1 will be described. FIG. 11 is a manufacturing flowchart for module 1. In step S11, while a plurality of printed circuit boards 2 is coupled to one another, electronic component 3 and other electronic components are mounted on each of printed circuit boards 2. In step S12 subsequent to step S11, resin portion 4 is formed by transfer molding on the upper surface of printed circuit board 2 so as to cover electronic component 3 and the like. Resin 4A that forms resin portion 4 is a thermosetting type.

In step S13 subsequent to step S12, a recess portion is formed in a position where printed circuit boards 2 are coupled together, and connection pattern 5 is exposed from the side surface of resin portion 4. In step S14 subsequent to step S13, conductive paste 6A is coated on the upper surface of resin portion 4 and is cured. At the same time, conductive paste 6A is also buried in the recess portion. In this way, shield film 6 is formed.

In step S15 subsequent to step S14, the coupling portion between printed circuit boards 2 is cut off. In this step, conductive paste 6A which is cured and printed circuit board 2 are cut off by a rotating dicing blade or the like so that module 1 is produced.

In module 1, shield film 6 is formed by printing conductive paste 6A. For this reason, voids or pinholes tend to be generated inside shield film 6. Further, since shield film 6 on a side portion of resin portion 4 is cut off in step S15, as a result of the cutting, a defect in shield film 6 tends to be caused. Furthermore, since resin portion 4 is formed by transfer molding, an internal stress (residual stress) tends to be caused, and therefore there may be a location at which a large stress is applied to shield film 6 depending on the location.

For these reasons, when a defect or a crack is caused in shield film 6, moisture infiltrates through such a place, resin portion 4 absorbs the moisture, and characteristics of the circuit change. Particularly, in the high-frequency circuit, a dielectric constant of resin portion 4 is changed by the moisture absorption, and an influence thereof exerted on high-frequency characteristics is markedly significant.

### SUMMARY OF THE INVENTION

One example of the present disclosure relates to a method for manufacturing a module having excellent reliability. The present disclosure relates to a method for manufacturing a module. The method for manufacturing a module may include the following steps:
placing a resin, which is in a non-flowable state, in a resin bath having an upper opening;
softening the resin in the resin bath until the resin becomes flowable;
placing, above the resin bath so as to close the upper opening, a substrate having a first surface on which an electronic component is mounted, with the electronic component facing downward, and sucking air in a space formed between the substrate and the resin in the resin bath;
immersing the electronic component into the softened resin after the softening the resin and the sucking air in the space, and bringing the first surface of the substrate into contact with a liquid surface of the softened resin;
pressurizing the softened resin and allowing the softened resin to flow into a gap between the substrate and the electronic component after the electronic component is immersed into the softened resin; and
curing the resin formed on the substrate and forming a resin portion on the substrate after the resin is allowed to flow into the gap.

The method may further include forming a metal film on a surface of the resin portion after the resin portion is formed. According to this method, it is possible to reduce an occurrence of cracks in the resin portion, peeling in an interface between the resin portion and the resin substrate, or a defect or generation of pinholes in the shield metal film, and realize a module having excellent reliability.

### BRIEF DESCRIPTION OF DRAWINGS

FIG. 1 is a cross sectional view of a high-frequency module as an example of a module according to an exemplary embodiment of the present disclosure.

FIG. 2 is an exemplary manufacturing flowchart for the high-frequency module illustrated in FIG. 1.

FIG. 3 is an exemplary schematic cross sectional view of an apparatus for forming a resin portion of the high-frequency module illustrated in FIG. 1.

FIG. 4 is an exemplary flowchart illustrating a procedure for forming the resin portion of the high-frequency module illustrated in FIG. 1.

FIG. 5 is an exemplary cross sectional view of the apparatus for forming the resin portion illustrated in FIG. 3 in a resin substrate mounting step.

FIG. 6 is an exemplary cross sectional view of the apparatus for forming the resin portion illustrated in FIG. 3 in an immersion step.

FIG. 7 is a cross sectional view of the apparatus for forming the resin portion illustrated in FIG. 3 in a pressurized inflow step.

FIG. 8 is a cross sectional view of a high-frequency module as an example of another module according to an exemplary embodiment of the present disclosure.

FIG. 9 is an exemplary manufacturing flowchart for the high-frequency module illustrated in FIG. 8.

FIG. 10 is a cross sectional view of a conventional high-frequency module.

FIG. 11 is a manufacturing flowchart for the high-frequency module illustrated in FIG. 10.

### DESCRIPTION OF EMBODIMENT

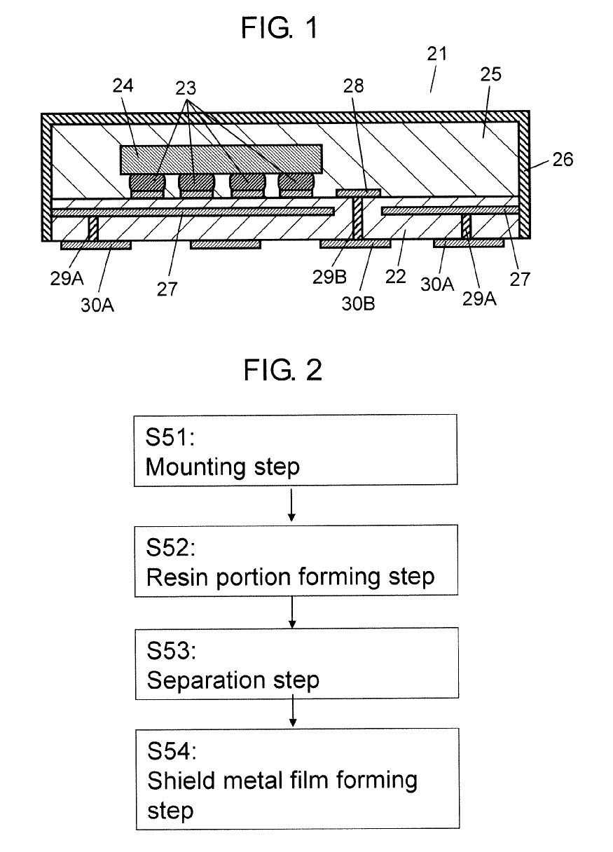

Hereinafter, a method for manufacturing a high-frequency module as an example of a module according to an exemplary embodiment of the present disclosure will be described with reference to the drawings. FIG. 1 is a cross sectional view of high-frequency module 21 according to this exemplary embodiment. High-frequency module 21 includes, for example, resin substrate 22, semiconductor device 24 as one example of an electronic component, resin portion 25, and shield metal film 26.

Resin substrate 22 is a multilayer substrate made of a glass epoxy material. Resin substrate 22 is, for example, a four-layer substrate having a thickness of, for example, 0.2 mm. An electronic component such as semiconductor device 24 or a chip part (not illustrated) is mounted on resin substrate 22 by means of solder 23.

Semiconductor device 24 is formed as a chip-size package having a thickness of, for example, 0.35 mm, and is mounted with a face thereof placed downward on an upper surface (first surface) of resin substrate 22 by flip-chip bonding through solder bumps. A pitch between the bumps is, for example, about 0.25 mm. In this case, a gap between the bumps is about 0.12 mm, and a gap between semiconductor device 24 and resin substrate 22 is about 0.12 mm. Further, a gap between the chip part and resin substrate 22 is about 0.08 mm.

A high-frequency circuit is partially formed in semiconductor device 24. When semiconductor device 24, the chip part (not illustrated), or the like is mounted on resin substrate 22, a high-frequency circuit such as a receiving circuit or a transmitting circuit is formed on resin substrate 22. Other than connecting semiconductor device 24 to resin substrate 22 by means of solder 23 and the bumps, semiconductor device 24 may be mounted on resin substrate 22 by forming stud bumps in semiconductor device 24 and using an anisotropic conductive film (ACF), an anisotropic conductive paste (ACP), a non-conductive film (NCF), a non-conductive paste (NCP), or the like.

Resin portion 25 is formed on an upper surface (first surface) of resin substrate 22 and buries therein semiconductor device 24, the chip part or the like. Resin portion 25 is formed of a thermosetting resin. Shield metal film 26 is formed to cover surfaces (upper surface and all four side surfaces) of resin portion 25.

Shield metal film 26 is a thin film formed by sputtering and having a thickness of, for example, about 1 μm, and is a very thin and dense film with little pinholes. Shield metal film 26 is made of, for example, copper having excellent conductivity. Accordingly, shield metal film 26 has excellent shield performance, and therefore high-frequency module 21 is resistant to interference or the like.

In this way, electronic components such as semiconductor device 24 are mounted on the first surface of resin substrate 22, and these electronic components form a circuit on resin substrate 22. Resin portion 25 is formed at least on the first surface of resin substrate 22, and shield metal film 26 covers the surface of resin portion 25.

Ground wiring pattern 27 is formed in resin substrate 22. Ground wiring pattern 27 is extended as far as to a peripheral portion of resin substrate 22, and an exposing portion of Ground wiring pattern 27 is formed on a side surface of resin substrate 22. Ground wiring pattern 27 and shield metal film 26 are connected to each other at the exposing portion.

Referring to FIG. 1, although Ground wiring pattern 27 is provided in an inner layer of resin substrate 22, it may be provided on the surface of the resin substrate. However, since Ground wiring pattern 27 is metallic, an adhesion force of Ground wiring pattern 27 to resin portion 25 is small. Therefore, if the exposing portion of Ground wiring pattern 27 is provided on the surface of resin substrate 22, peeling tends to be caused in an interface between Ground wiring pattern 27 and resin portion 25 in, for example, separation step S53 which will be described later. Accordingly, it is preferable to provide Ground wiring pattern 27 in the inner layer as much as possible and establish a connection to shield metal film 26.

Further, the exposing portion of Ground wiring pattern 27 is extended from the inner layer of resin substrate 22. Therefore, even if shield metal film 26 has a thickness of, for example, 1 μm, it is possible to reduce an occurrence of cracks or the like in shield metal film 26. As a result, the shield performance of high-frequency module 21 improves.

Ground wiring pattern 27 is connected to mounting pad 30A disposed on a bottom surface of resin substrate 22 through connection conductor 29A. Then, when high-frequency module 21 is mounted on a parent substrate (not illustrated), mounting pad 30A is connected to a ground of the parent substrate. With this arrangement, the high-frequency circuit formed on resin substrate 22 is surrounded by shield metal film 26 in upper and transverse directions thereof. Accordingly, it is possible to prevent a high-frequency signal that is processed (or generated) by this high-frequency circuit from leaking outside, or to reduce a high-frequency noise generated outside and jumping into the high-frequency circuit in high-frequency module 21.

In this example, Ground wiring pattern 27 is formed in a second layer of resin substrate 22 counted from the upper surface thereof. This means that Ground wiring pattern 27 is formed in the inner layer of resin substrate 22. Therefore, the high-frequency circuit formed on resin substrate 22 is surrounded by Ground wiring pattern 27 and shield metal film 26. As a result, high-frequency module 21 is further resistant to interference.

In addition, Ground wiring pattern 27 is preferably not connected to the ground of the high-frequency circuit. This means that the ground of the high-frequency circuit is connected to ground terminal 28 on the surface of resin substrate 22, and is led to mounting pad 30B on the bottom surface of resin substrate 22 through connection conductor 29B that brings the upper and bottom surfaces of resin substrate 22 into conduction. In this way, the ground of the high-frequency circuit and shield metal film 26 are separated in terms of high frequency (electrically). As a result, it is hardly possible that a high-frequency signal of the high-frequency circuit is radiated outside from shield metal film 26, or a high-frequency noise that hops onto shield metal film 26 infiltrates into the high-frequency circuit.

Next, a method for manufacturing high-frequency module 21 will be described with reference to FIG. 2. FIG. 2 is a manufacturing flowchart for high-frequency module 21.

First, in mounting step S51, semiconductor device 24 or the chip part is mounted on resin substrate 22 while a plurality of resin substrates 22 is coupled together (as a main substrate), and the high-frequency circuit is formed on resin substrate 22. Specifically, cream-based solder 23 is printed on the upper surface of resin substrate 22, semiconductor device 24 or the chip part is mounted thereon, and these components are soldered to resin substrate 22 by reflow soldering. The high-frequency circuit is formed on a bottom surface side of semiconductor device 24, and semiconductor device 24 is mounted by flip-chip bonding in a direction in which a surface where the high-frequency circuit is formed faces resin substrate 22 (in a face-down direction).

In mounting step S51, after semiconductor device 24 or the chip part is mounted, characteristics of the high-frequency circuit are tested. In this test, a correction work may be performed on the circuit having characteristics outside a predetermined range so that the high-frequency circuit satisfies the predetermined characteristics. This correction work may involve replacing the chip part with another chip part having a different constant, trimming of a pattern inductor, or the like.

In resin portion forming step S52 subsequent to mounting step S51, resin portion 25 is formed on the upper surface of resin substrate 22. Resin portion 25 is formed using resin 25A of a thermosetting type.

In separation step S53 subsequent to resin portion forming step S52, coupled resin substrates 22 are separated into individual pieces. Specifically, coupled resin substrates 22 are cut using a rotating dicing blade into individual pieces. As a result of the cutting, resin portion 25 formed on a coupling portion of resin substrate 22 and the coupling portion of resin substrate 22 are removed so that coupled resin substrates 22 are separated into individual resin substrates 22. Further, as a result of the cutting, the exposing portion of Ground wiring pattern 27 is formed on a side surface of resin substrate 22.

In shield metal film forming step S54 subsequent to separation step S53, shield metal film 26 is formed on surfaces (upper and side surfaces) of resin portion 25 and side surfaces of resin substrate 22. Specifically, the metal film is formed on the surfaces of resin portion 25 and the side surfaces of resin substrate 22 by sputtering. As a result, shield metal film 26 is connected to Ground wiring pattern 27 at the exposing portion of Ground wiring pattern 27 provided on a side surface of resin substrate 22.

In this way, after resin portion 25 is formed by curing the resin as described later, but before shield metal film 26 is formed, side surfaces of resin portion 25 are formed, and the exposing portion of Ground wiring pattern 27 is exposed. Then, when shield metal film 26 is formed, shield metal film 26 and Ground wiring pattern 27 are connected to each other in this exposing portion. Specifically, electronic components such as semiconductor device 24 are fitted while the plurality of resin substrates 22 is coupled together through individual coupling portions, and the coupling portions are cut off when the exposing portion is exposed.

Then, subsequent to shield metal film forming step S54, a final characteristic test may be performed on high-frequency module 21 so that high-frequency module 21 is completed.

In the above-mentioned manufacturing method, shield metal film 26 is formed after separation step S53. For this reason, flaws by the rotating dicing blade are hardly caused in shield metal film 26. This fact is particularly important if a thickness of shield metal film 26 is small. With this arrangement, even if the thickness of shield metal film 26 formed of a sputtered thin film is 1 μm, it is possible to reduce the occurrence of the flaws.

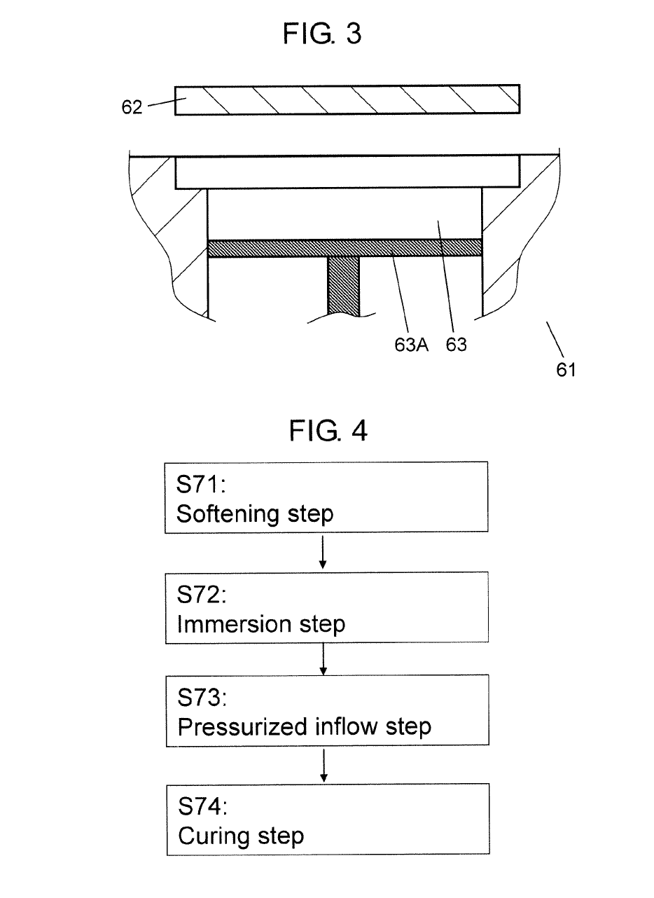

Next, resin portion forming step S52 will be described in detail. First, in resin portion forming step S52, resin portion forming apparatus 61 for forming resin portion 25 on resin substrate 22 will be described. FIG. 3 is a schematic cross sectional view of the resin portion forming apparatus according to this exemplary embodiment.

Resin portion forming apparatus 61 may include resin substrate mounting portion 62 and resin bath 63. Resin substrate 22 is mounted on resin substrate mounting portion 62 while semiconductor device 24 faces downwardly. Therefore, resin substrate mounting portion 62 is structured to hold resin substrate 22 thereto.

Resin bath 63 is provided below resin substrate mounting portion 62, has an open upper surface and a space in which resin 25A is thrown. Resin bath 63 may be movable in a vertical direction. In addition, bottom portion 63A of resin bath 63 may be independent from a movement of entire resin bath 63 and may be movable in a vertical direction (vertical direction in FIG. 3) independently.

Heating portions (not illustrated) are individually provided in resin substrate mounting portion 62 and resin bath 63, and these heating portions individually heat resin substrate 22 and resin 25A. Further, resin portion forming apparatus 61 is provided with a suction portion (not illustrated) including a compressor or the like. The suction portion sucks air in resin bath 63 or between resin bath 63 and resin substrate mounting portion 62 so that formation of resin portion 25 can be performed substantially under vacuum.

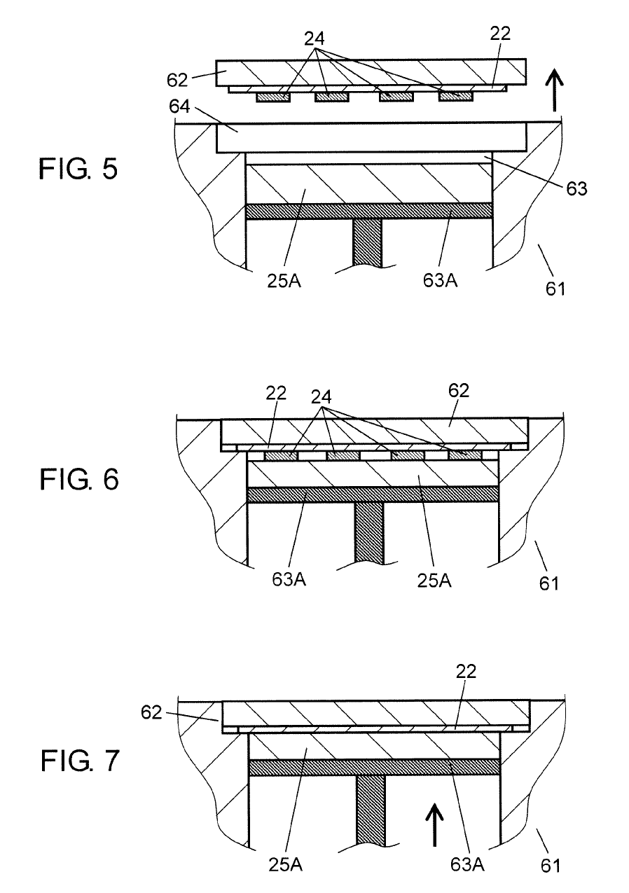

FIG. 4 is a flowchart illustrating details of resin portion forming step S52 according to this exemplary embodiment, and FIGS. 5 to 7 are cross sectional views of resin portion forming apparatus 61 in individual steps included in resin portion forming step S52. Hereinafter, resin portion forming step S52 using resin portion forming apparatus 61 will be described in detail according to the sequential steps of FIG. 4.

In FIGS. 4 and 5, in softening step S71 subsequent to mounting step S51, resin substrate 22 is mounted on resin substrate mounting portion 62. Resin substrate 22 is mounted above resin bath 63 so that a mounting surface (first surface) thereof on which semiconductor device 24 or the chip part is mounted faces downward.

In addition, resin 25A in a non-flowable state (unmelted and solid state, or gel state) is thrown into resin bath 63, and resin 25A is heated and softened until it becomes flowable. In parallel with this process, air in space 64 between resin 25A and resin substrate 22 may be sucked. In that process, the air is sucked until space 64 becomes substantially a vacuum state, and the suction of the air is stopped after resin 25A is completely melted. Since resin bath 63 and resin substrate mounting portion 62 have been heated in advance to a temperature at which resin 25A melts, it is possible to soften resin 25A in a short period of time.

Here, the process of sucking the air in space 64 may be performed either before or after the process of softening resin 25A to a flowable state. However, it is possible to shorten the time by performing these two processes in parallel with each other.

Resin 25A before being thrown into resin bath 63 is granular (solid state), and a predetermined amount of resin 25A measured by a measuring container is thrown into resin bath 63. Resin 25A does not exhibit fluidity at a temperature lower than a first temperature, exhibits fluidity in a range of softening temperature equal to or higher than the first temperature and lower than a second temperature which is higher than the first temperature, and is cured at a third temperature which is equal to or higher than the second temperature.

Since resin 25A is granular when resin 25A is thrown into resin bath 63, it is possible to accurately measure an amount of resin 25A. It is also possible to easily automate the measurement and throwing. In addition to the solid state, resin 25A may be in a gel state. In such a case, since resin 25A is already in a gel state at room temperature, it is possible to shorten the time required until it becomes softened (exhibiting fluidity) and thereby the productivity is improved.

Softening step S71 is performed according to the following procedure by using resin portion forming apparatus 61. Resin substrate mounting portion 62 and resin bath 63 are heated by the heating portions in advance so that a range of softening temperature of resin substrate mounting portion 62 and resin bath 63 becomes equal to or higher than a temperature at which resin 25A exhibits fluidity but a temperature lower than the third temperature at which resin 25A cures. For example, resin 25A is a thermosetting epoxy resin that exhibits smaller fluidity at a temperature lower than 140° C., is softened the most and exhibits fluidity at a temperature equal to or higher than 140° C. but lower than 175° C., and is cured at a temperature equal to or higher than 175° C. In this case, the temperature of resin substrate mounting portion 62 and resin bath 63 is set to a temperature equal to or higher than 140° C. but lower than 175° C.

Resin substrate mounting portion 62 may be structured to slide in a horizontal direction in FIG. 3, and, when resin substrate mounting portion 62 slides, an area above resin bath 63 is opened. In this state, a specified amount of resin 25A is thrown from above resin bath 63. Immediately after resin 25A is thrown in this way, resin 25A starts to be heated.

In addition, since resin substrate mounting portion 62 opens an area therebelow by being slid, resin substrate 22 is absorbed onto a bottom surface of resin substrate mounting portion 62 while semiconductor device 24 or chip part is directed downward. Then, resin substrate mounting portion 62 slides again and stops at a position above resin bath 63. When throwing of resin 25A and mounting of resin substrate 22 are completed in this way, sucking air in space 64 is started. Then, after resin 25A melts to become a complete flowable state, the suction is stopped, and the vacuum state at this moment is maintained.

According to the foregoing description, resin substrate mounting portion 62 horizontally slides. However, other than this method, resin bath 63 may slide instead. Further, at least one of resin substrate mounting portion 62 and resin bath 63 may be slid in a vertical direction. However, in this case, a distance between resin bath 63 and resin substrate mounting portion 62 is adjusted to such a degree that allows throwing operation of resin 25A and mounting operation of resin substrate 22.

Next, immersion step S72 subsequent to softening step S71 will be described with reference to FIG. 6. FIG. 6 is a cross sectional view of resin portion forming apparatus 61 in immersion step S72. In immersion step S72, semiconductor device 24 or the chip part is immersed in resin 25A that has been softened to a flowable state, and the first surface of resin substrate 22 is brought into contact with a liquid surface of softened resin 25A.

For example, immersion step S72 is performed as described below. While resin bath 63 and bottom portion 63A are moved upward (direction of an arrow in FIG. 5) at speeds substantially equal to each other so that resin substrate 22 is held between resin bath 63 and resin substrate mounting portion 62. During this operation, it is necessary not to create a gap between resin bath 63 and resin substrate 22. For this purpose, it is preferable that a rubber gasket (not illustrated) or the like be provided at a position that makes contact with the bottom surface of resin substrate 22 in resin bath 63.

Then, after resin bath 63 ascends to a specified position, that is, a position at which resin bath 63 makes contact with resin substrate 22, resin bath 63 is stopped. In this state, the liquid surface of resin 25A does not yet make contact with the first surface of resin substrate 22. With this arrangement, an amount of resin 25A overflowing from resin bath 63 can be made smaller. However, at the same time, it is preferable that semiconductor device 24 or the chip part be kept in contact with the liquid surface of resin 25A. With this arrangement, by an action of surface tension of resin 25A, resin 25A creeps up along a side face of semiconductor device 24 or the like, or part of it infiltrates into a narrow gap between resin substrate 22 and semiconductor device 24 or the chip part. As a result, in subsequent pressurized inflow step S73, resin 25A tends to be filled into a very narrow gap between resin substrate 22 and semiconductor device 24 or chip part. In addition, bottom portion 63A continues its ascending even after the movement of resin portion 25 is stopped. As a result, the liquid surface of resin 25A makes contact with the first surface of resin substrate 22.

FIG. 7 is a cross sectional view of resin portion forming apparatus 61 in pressurized inflow step S73 subsequent to immersion step S72. When immersion step S72 completes, electronic components such as semiconductor device 24 appear to be completely immersed in resin 25A. However, there are some gaps which are not filled with resin 25A among the gaps between resin substrate 22 and semiconductor device 24 or the chip part. To cope with this, pressurized inflow step S73 is performed after immersion step S72.

In pressurized inflow step S73, resin 25A is pressurized in a direction of an arrow shown in FIG. 7 so that resin 25A is allowed to flow into unfilled gaps forcibly by the pressure. At this point, space surrounded by resin bath 63 and resin substrate 22 is filled with resin 25A with exceptions of unfilled portions among the gaps between resin substrate 22 and semiconductor device 24 or the chip part. Accordingly, when resin 25A is pressurized, bottom portion 63A hardly ascends, and only the pressure of resin 25A increases. Then, the pressurization is continued until such a pressure reaches a specified value, and that pressure is maintained. In pressurized inflow step S73, the temperature of resin 25A is kept within the second temperature range. With this arrangement, resin 25A is reliably filled into the gaps between resin substrate 22 and semiconductor device 24 or the chip part.

In this exemplary embodiment, solder 23 is tin and silver based lead-free solder, and melting point thereof is preferably about 200° C. Since semiconductor device 24 or the like and resin substrate 22 are connected together by solder 23 having a melting point equal to or higher than the second temperature, solder 23 does not melt in pressurized inflow step S73. Accordingly, an electric link between resin substrate 22 and semiconductor device 24 or the chip part is hardly disconnected.

In curing step S74 subsequent to pressurized inflow step S73, resin 25A is further heated until the temperature thereof reaches the third temperature so that resin 25A cures. As a result, resin portion 25 is formed on resin substrate 22. In curing step S74, it is preferable to maintain the pressure that is applied in pressurized inflow step S73 at least during a period until the fluidity of resin 25A ceases to exist. With this arrangement, voids or the like are hardly left in the gaps between resin substrate 22 and semiconductor device 24 or the chip part.

High-frequency module 21 is manufactured through the manufacturing method described above, and a thin film is formed on the surface of resin portion 25 by sputtering in shield metal film forming step S54. Since shield metal film 26 is a sputtered thin film and formed very densely, it has little pinholes or the like. With this arrangement, it is possible to manufacture high-frequency module 21 having excellent shield performance and hardly causing a malfunction by a noise or the like.

However, the sputtered thin film is very thin. Therefore, if there is a minute flaw in the film, there is a high chance of the flaw developing into cracks or the like due to an internal stress of resin portion 25, deformation caused by the stress, or a stress caused in separation step S53. Particularly, the stress tends to concentrate on an interface between resin portion 25 and resin substrate 22 due to a difference in coefficient of linear expansion between resin portion 25 and resin substrate 22, and cracks tend to be caused in the interface.

According to this exemplary embodiment, semiconductor device 24 or the chip part is immersed in resin 25A in a flowable state in immersion step S72, resin 25A is compressed in pressurized inflow step S73, and therefore resin 25A is buried into a gap between resin substrate 22 and semiconductor device 24 or the chip part. This arrangement makes it possible to reduce the internal stress caused by ununiformity of a flow of resin 25A or the like as compared with the transfer molding. As a result, a residual stress in resin substrate 22 or resin portion 25 is reduced, at the same time, strains and deformations thereof can also be reduced, a stress of shield metal film 26 is reduced, and peeling or cracks of shield metal film 26 are hardly caused. Accordingly, resin portion 25 hardly absorbs moisture under a high humidity environment, and high-frequency module 21 having high reliability can be realized.

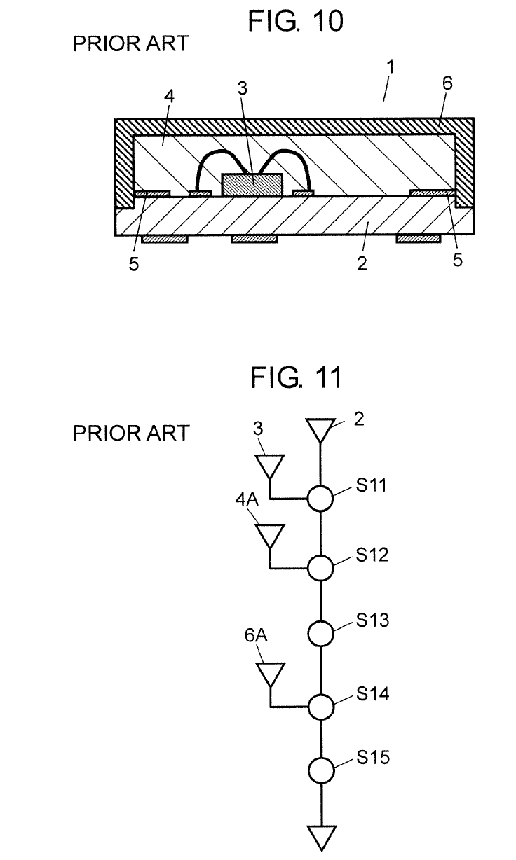

An adhesion force between metal and resin portion 25 is small. This tends to cause peeling or the like in an interface between Ground wiring pattern 27 and resin portion 25 in separation step S53 or the like if Ground wiring pattern 27 is provided on an entire periphery of the surface layer of resin substrate 22. In the conventional module illustrated in FIGS. 10 and 11, conductive paste 6A is buried in a peeling portion so that the peeling portion is reinforced. In contrast, since shield metal film 26 according to this exemplary embodiment is formed by sputtering, shield metal film 26 is not formed in the peeling portion.

For this reason, according to this exemplary embodiment, Ground wiring pattern 27 is provided in the inner layer of resin substrate 22. With this structure, a metallic object is not interposed between resin substrate 22 and resin portion 25, and resin portion 25 is formed directly on resin substrate 22. Accordingly, an adhesion strength of resin portion 25 is high. Further, since the exposing portion of Ground wiring pattern 27 is held and reinforced from above and below by a glass base material, peeling or cracks are hardly caused by a stress incurred during separation step S53. Therefore, even if shield metal film 26 has a thickness of, for example, 1 μm, cracks or the like are hardly caused in shield metal film 26.

Further, since a pressure is applied in pressurized inflow step S73, resin 25A is reliably filled into a very narrow gap between resin substrate 22 and semiconductor device 24 or the chip part. In addition, since a pressure is applied to semiconductor device 24 or the chip part only in pressurized inflow step S73, this can reduce a stress exerted on semiconductor device 24 or the chip part. Therefore, deformation of semiconductor device 24, the chip part, or resin substrate 22 is small. As a result of this, variations in a distance between the high-frequency circuit in semiconductor device 24 and shield metal film 26, a distance between the high-frequency circuit in semiconductor device 24 and resin substrate 22, further, a distance between resin substrate 22 and shield metal film 26, or the like can be made smaller. Consequently, variations in stray capacitance values therebetween can be made smaller, and therefore high-frequency module 21 having small variations can be realized.

In addition, semiconductor device 24 or the chip part is merely immersed in resin 25A in a flowable state in immersion step S72, and resin 25A is caused to flow in pressurized inflow step S73. Therefore, a distance in which resin 25A flows is very small as compared with the transfer molding. As a result, the internal stress caused by ununiformity in the flow of resin 25A after resin 25A cures is also small. This makes it possible to reduce a strain (deformation) of semiconductor device 24, the chip part, resin substrate 22, resin portion 25 themselves, or the like, and therefore reduce variations in the stray capacitance values. Thus, it is possible to realize high-frequency module 21 having a small variation in the characteristics of the high-frequency circuit.

According to this exemplary embodiment, in particular, since semiconductor device 24 is mounted with a face thereof placed downward by flip-chip bonding, a clearance between semiconductor device 24 and resin substrate 22 is very small. This causes a large stray capacitance between the high-frequency circuit formed in semiconductor device 24 and Ground wiring pattern 27. A variation in this stray capacitance, in particular, exerts a great influence on the characteristics of the high-frequency circuit of semiconductor device 24. This is a very important issue in burring the high-frequency circuit in resin 25A.

To state it differently, even the high-frequency circuit that has passed the test of high-frequency characteristics in mounting step S51 may fail a test conducted after resin portion 25 is formed, if the strain of semiconductor device 24, resin substrate 22, or resin portion 25 themselves is large. However, once the resin portion 25 is formed, a repairing work is very difficult, and there is no other way but to discard the product. This may lead to an extreme reduction in the yield.

To cope with this, a distance in which resin 25A flows is made smaller by the above-mentioned manufacturing method to thereby reduce the residual stress remaining in resin 25A, and the stress exerted on semiconductor device 24, the chip part, resin substrate 22, resin portion 25 themselves, or the like is reduced. With this arrangement, it is possible to reduce a variation in the high-frequency characteristics after resin portion 25 is formed, and improve the yield of high-frequency module 21.

Further, reducing the residual stress exerts a great influence on reliability of the characteristics of high-frequency module 21 over a long period. Expansion and contraction are caused in resin portion 25 or resin substrate 22 by a change in temperature or the like, and this may change an internal stress distribution inside resin portion 25. For this reason, an amount of strain of semiconductor device 24, resin substrate 22, or resin portion 25 changes. As a result, values of the stray capacitances between semiconductor device 24 and resin substrate 22 (Ground wiring pattern 27), semiconductor device 24 and shield metal film 26, and the like may change from the values during manufacturing. To cope with this, by reducing the internal stress by the above-mentioned manufacturing method, it is possible to realize high-frequency module 21 that can maintain the stable characteristics over a long period of time also against a change in temperature or the like.

Since resin 25A is forcibly filled in the gap in pressurized inflow step S73, it is also possible to reliably fill resin 25A into the gap between semiconductor device 24 and resin substrate 22 as compared with a printing method or a method by potting. Accordingly, it is possible to realize high-frequency module 21 extremely excellent in reliability.

As described above, since it is possible to reduce a chance of destroying semiconductor device 24 or the chip part by a compression pressure and reduce deformation of semiconductor device 24, the thickness of semiconductor device 24 can be made smaller. For this reason, even if the thickness of resin portion 25 that is formed on semiconductor device 24 or the chip part is small, resin portion 25 can be reliably formed above semiconductor device 24 or the chip part as compared with the case of conventional transfer molding. This is because resin portion 25 above semiconductor device 24 (or the chip part) is formed by immersion in immersion step S72. With this arrangement, a low-profile high-frequency module 21 can be realized. According to this exemplary embodiment, high-frequency module 21 having a thickness of 0.8 mm is realized.

Using the above-mentioned manufacturing method, high-frequency module 21 having a thickness of 0.5 mm is realized. In this case, resin substrate 22 has a thickness of 0.1 mm. and semiconductor device 24 has a thickness of 0.25 mm. Although the thicknesses are very small, deformation is also small, and high-frequency module 21 having a small variation in the characteristics is realized. Further, although a gap between semiconductor device 24 and resin substrate 22 is 0.08 mm which is very narrow, resin 25A is reliably filled into this gap. Moreover, although the thickness of resin portion 25 above semiconductor device 24 or the chip part is 0.07 mm which is very thin, resin portion 25 having a stable thickness is formed.

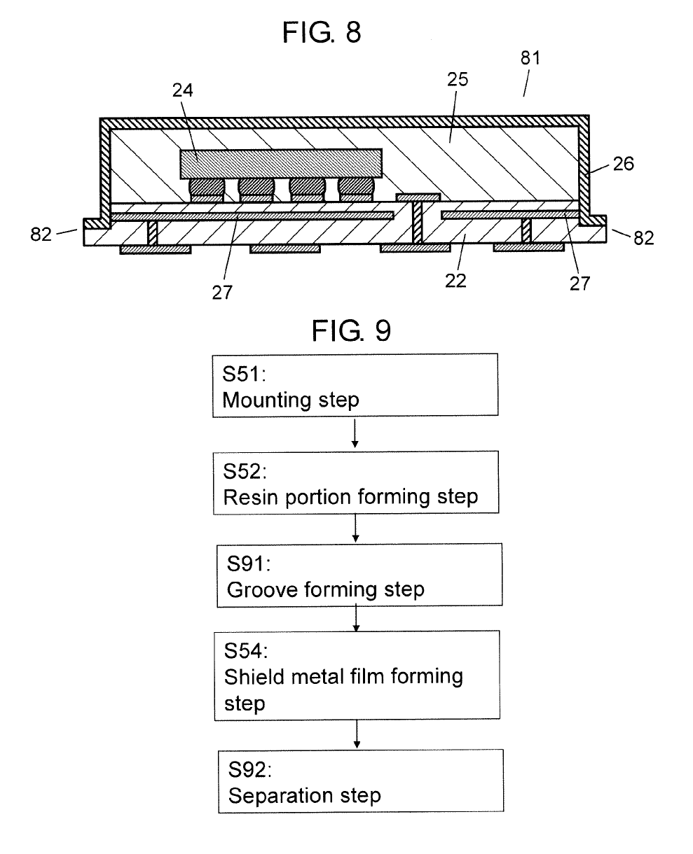

Next, another high-frequency module 81 according to another exemplary embodiment is described with reference to FIGS. 8 and 9. FIG. 8 is a cross sectional view of high-frequency module 81. According to high-frequency module 21 illustrated in FIG. 1, the side surface of resin substrate 22 and the side surface of resin portion 25 are in line with each other, and shield metal film 26 is extended and formed as far as to a lower end of the side surface of resin substrate 22. In contrast, according to high-frequency module 81, step portion 82 is formed in a lower portion of the side surface of resin substrate 22, and shield metal film 26 is formed as far as to an upper end of step portion 82 on the side surface of resin substrate 22. However, a portion on an upper side of step portion 82 on the side surface of resin substrate 22 is in line with the side surface of resin portion 25, the exposing portion of Ground wiring pattern 27 is also formed above step portion 82 on the side surface of resin substrate 22.

Next, a method for manufacturing high-frequency module 81 will be described with reference to FIG. 9. FIG. 9 is a manufacturing flowchart for the high-frequency module. In FIG. 9, steps identical with those illustrated in FIG. 2 are identified with the same reference marks as those used in FIG. 2, and descriptions thereof will be simplified. The steps up to resin portion forming step S52 are the same as those of the method for manufacturing high-frequency module 21.

In groove forming step S91 subsequent to resin portion forming step S52, coupled resin substrates 22 are not cut into individual pieces but remain as being coupled together with the coupling portion left intact. In this state, a groove is formed in resin portion 25 and resin substrate 22 in the coupling portion so that the exposing portion of Ground wiring pattern 27 exposes from the side surface of resin substrate 22.

After groove forming step S91, shield metal film forming step S54 is performed, and shield metal film 26 is formed in the groove formed on a periphery (upper and side surfaces) of resin portion 25 and resin substrate 22. The groove is present on the upper surface of step portion 82 and on an upper side of step portion 82 of the side surface of resin substrate 22.

Then, after shield metal film forming step S54, separation step S92 is performed. In separation step S92, the coupling portion of resin substrates 22 is cut off by a rotating dicing blade or the like having a blade thickness smaller than that of the groove. To state it differently, after shield metal film 26 is formed, the coupling portion is cut at a width smaller than that of the groove. With this arrangement, a stress incurred during cutting shield metal film 26 in separation step S92 can be reduced, and flaws are hardly caused in shield metal film 26. As a result, an excellent shield can he realized. In this case, shield metal film forming step S54 can be performed while resin substrates 22 are coupled together. In addition, if the characteristic test is conducted in between shield metal film forming step S54 and separation step S92, the test can also be conducted while resin substrates 22 are coupled together, and therefore the productivity becomes excellent.

In the foregoing description, a high-frequency module is taken as an example. However, the present disclosure is not limited to the example, and may be applied to a module in which electronic components are mounted on resin substrate 22, covered by resin portion 25, and shielded by shield metal film 26. Further, although the high-frequency circuit is formed of semiconductor device 24, other configuration can be adopted. In the foregoing, although the description is given of an example in which semiconductor device 24 is mounted while a plurality of resin substrates 22 is coupled together, and resin substrates 22 are separated into individual pieces at the coupling portions, individual resin substrates 22 may be used, instead. In such a case, instead of cutting, the side surfaces may be ground.

### INDUSTRIAL APPLICABILITY

The module according to the present disclosure provides an effect of excellent reliability and is useful when it is used in a high-frequency module or the like that is mounted in electronic equipment or the like.

### REFERENCE MARKS IN THE DRAWINGS

21, 81 High-frequency module
22 Resin substrate
23 Solder
24 Semiconductor device
25 Resin portion
25A Resin
26 Shield metal film
27 Ground wiring pattern
28 Ground terminal
29A, 29B Connection conductor
30A, 30B Mounting pad
61 Resin portion forming apparatus
62 Resin substrate mounting portion
63 Resin bath
63A Bottom portion
64 Space
82 Step portion

1. A method for manufacturing a module, the method comprising steps of:
placing a resin, which is in a non-flowable state, in a resin bath having an upper opening;
softening the resin in the resin bath until the resin becomes flowable;
placing, above the resin bath so as to close the upper opening, a substrate having a first surface on which an electronic component is mounted, with the electronic component facing downward, and sucking air in a space formed between the substrate and the resin in the resin bath;
immersing the electronic component into the softened resin after the softening the resin and the sucking air in the space, and bringing the first surface of the substrate into contact with a liquid surface of the softened resin;
pressurizing the softened resin and allowing the softened resin to flow into a gap between the substrate and the electronic component after the electronic component is immersed into the softened resin; and
curing the resin formed on the substrate and forming a resin portion on the substrate after the resin is allowed to flow into the gap.

2. The method for manufacturing a module according to claim 1, the method further comprising:
forming a metal film on a surface of the resin portion after the resin portion is formed.

3. The method of claim 2, wherein the metal film is formed by sputtering.

4. The method for manufacturing a module according to claim 1,
wherein the softening of the resin and the sucking of air in the space are performed in parallel with each other.

5. The method for manufacturing a module according to claim 1,
wherein the resin is a thermosetting resin that does not have fluidity at a temperature lower than a first temperature, has fluidity in a temperature range equal to or higher than the first temperature and lower than a second temperature which is higher than the first temperature, and cures at a third temperature which is equal to or higher than the second temperature, and
in the allowing of the resin to forcibly flow into the gap, a temperature of the resin is kept in the temperature range.

6. The method for manufacturing a module according to claim 5,
wherein the electronic component and the substrate are connected by solder having a melting point equal to or higher than the second temperature.

7. The method for manufacturing a module according to claim 5,
wherein, in the curing of the resin, the resin is heated until a temperature of the resin reaches the third temperature or higher while a pressure is applied to the resin.

8. A method for manufacturing a module, the method comprising steps of:
placing a resin, which is in a non-flowable state, in a resin bath having an upper opening;
softening the resin in the resin bath until the resin becomes flowable;
placing, above the resin bath so as to close the upper opening, a main substrate having a first surface on which plurality electronic components are mounted, with the plurality electronic components facing downward, and sucking air in a space formed between the main substrate and the resin in the resin bath;
immersing the plurality electronic components into the softened resin after the softening the resin and the sucking air in the space, and bringing the first surface of the main substrate into contact with the softened resin;
pressurizing the resin and allowing the resin to flow into a gap between the main substrate and the plurality electronic components after the plurality electronic components is immersed into the softened resin;
curing the resin and forming a resin portion on the main substrate after the resin is allowed to flow into the gap; and
after the step of curing, cutting the main substrate into a plurality of modules each includes one of the plurality of electronic components.

9. The method of claim 8, wherein:
each of the modules includes a ground wiring pattern,
after the step of cutting the ground wiring patter is exposed at a side surface of each of the module, and
the method further comprising:
forming a metal film on a surface of cured resin of each of the modules so that the metal film is connected to the ground wiring pattern.

10. The method for manufacturing a module according to claim 8,
wherein, after the forming of the shield metal film, the main substrate is cut off.

11. The method for manufacturing a module according to claim 8, further comprising, before the step of cutting off:
forming a groove at a portion to be cut in the main resin portion and the main substrate so that the ground wiring pattern exposes from a side surface of each of the modules before cutting off; and
forming a metal film on the cured resin on the main substrate so that the metal film connects the ground wiring pattern,
wherein, in the step of cutting off, the main substrate is cut off together with the metal film at a width smaller than a width of the groove.

12. A module including:
a substrate including a first surface;
an electronic component mounted on the first surface of the substrate;
a ground wiring pattern;
a resin portion burying the electronic component therein and formed at least on the first surface of the substrate; and
a shield metal film covering a surface of the resin portion,
wherein the Ground wiring pattern is embedded in the substrate and connected to the shield metal film at a side surface of the module.

13. The module of claim 12, wherein:
the side surface of the module has a step including a vertical face and horizontal face, and
the ground wiring pattern is connected to the shield metal file at the vertical face.

14. The module of claim 12, wherein:
the module include another ground wiring pattern connected to the electronic component, and
the ground wiring pattern and the another ground wiring patter are not connected.

15. The module of claim 12, wherein the ground wiring pattern is disclose at least below the electronic component.
